(19) United States
(12) Patent Application Publication
(10) Pub. No.: US 2010/0296842 A1
(43) Pub. Date: Nov. 25, 2010

(54) ELECTRON EMITTING ELEMENT, ELECTRON EMITTING DEVICE, LIGHT EMITTING DEVICE, IMAGE DISPLAY DEVICE, AIR BLOWING DEVICE, COOLING DEVICE, CHARGING DEVICE, IMAGE FORMING APPARATUS, ELECTRON-BEAM CURING DEVICE, AND METHOD FOR PRODUCING ELECTRON EMITTING ELEMENT

(76) Inventors: Yasuo IMURA, Osaka-shi (JP); Hiroyuki Hirakawa, Osaka-shi (JP); Ayae Nagaoka, Osaka-shi (JP); Tadashi Iwamatsu, Osaka-shi (JP); Kanako Hirata, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/696,905

(22) Filed: Jan. 29, 2010

(30) Foreign Application Priority Data
May 19, 2009 (JP) 2009-121454
Sep. 15, 2009 (JP) 2009-213572

(51) Int. Cl. G03G 15/02; H01J 1/02; H01L 51/54; H05B 41/00; H01T 23/00; H01J 9/02

(52) U.S. Cl. 399/168; 313/235; 313/504; 315/326; 361/230; 445/51

(57) ABSTRACT

An electron emitting element of the present invention includes an electron acceleration layer that includes insulating fine particles but does not include conductive fine particles, the electron acceleration layer being provided between an electrode substrate and a thin-film electrode. This electron emitting element accelerates electrons in the electron acceleration layer and emits the electrons from the thin-film electrode, when a voltage is applied between the electrode substrate and the thin-film electrode. Accordingly, the electron emitting element of the present invention makes dielectric breakdown hard to occur. Further, this electron emitting element is produced easily at low cost and capable of emitting a steady and sufficient amount of electrons.

This Nonprovisional application claims priority under 35 U.S.C. §119(a) on Patent Applications No. 2009-121454 filed in Japan on May 19, 2009 and No. 2009-213572 filed in Japan on Sep. 14, 2009, the entire contents of which are hereby incorporated by reference.

### TECHNICAL FIELD

The present invention relates to an electron emitting element for emitting electrons by application of a voltage.

### BACKGROUND ART

A Spindt-type electrode and a carbon nanotube electrode (CNT) have been known as conventional electron emitting elements. Applications of such conventional electron emitting elements to, for example, the field of Field Emission Display (FED) have been studied. Such electron emitting elements are caused to emit electrons by tunnel effect resulting from formation of an intense electric field of approximately 1 GV/m that is produced by application of a voltage to a pointed section.

However, each of these two types of the electron emitting elements has an intense electric field in the vicinity of a surface of an electron emitting section. Accordingly, electrons emitted obtain a large amount of energy due to the electric field. This makes it easy to ionize gas molecules. However, cations generated in the ionization of the gas molecules are accelerated in a direction of a surface of the element due to the intense electric field and collide with the surface. This causes a problem of breakdown of the element due to sputtering. Further, ozone is generated before ions are generated, because oxygen in the atmosphere has dissociation energy that is lower than ionization energy. Ozone is harmful to human bodies, and oxidizes various substances because of its strong oxidizing power. This causes a problem in that members around the element are damaged. In order to prevent this problem, the members used around the electron emitting element are limited to members that have high resistance to ozone.

In order to solve this problem, an MIM (Metal Insulator Metal) type and an MIS (Metal Insulator Semiconductor) type have been known as other types of electron emitting elements. These electron emitting elements are surface-emission-type electron emitting elements which accelerate electrons by utilizing quantum size effect and an intense electric field in the element so that electrons are emitted from a flat surface of the element. These electron emitting elements do not require an intense electric field outside the elements, because the electrons which are accelerated in respective electron acceleration layers inside the elements are emitted to the outside. Therefore, each of the MIM type and the MIS type electron emitting elements can overcome the problems such that (i) the element is broken down by the sputtering which occurs due to ionization of gas molecules and (ii) ozone is generated, in the Spindt-type, CNT type, and BN type electron emitting elements.

In general MIM type electron emitting element, a thickness of the electron acceleration layer inside the element needs to be thin and set to approximately some nm so that the tunnel effect is produced. Accordingly, a problem such as a pinhole or dielectric break down tends to occur. This makes it very difficult to form a high-quality electron acceleration layer. In order to solve this problem, Patent Literature 1 discloses an electron emitting element that makes dielectric breakdown hard to occur and that has an improved process yield and reproducibility, by including, as the electron acceleration layer, an insulating film containing metal or semiconductor fine particles. This Patent Literature 1 discloses three examples of a method for producing the insulating thin film in which fine particles made of metal or the like are dispersed. The three examples of the method are: (1) a method of applying, by a spin coating method, a dispersion solution in which metal fine particles are mixed with an insulator liquid coating agent; (2) a method by thermal decomposition after application of a dispersion solution in which an organic metal compound solution is mixed with an insulator liquid coating agent; and (3) a vacuum deposition method of an insulator by a plasma or thermal CVD method or the like.

### CITATION LIST

Patent Literature 1

Japanese Patent Application Publication, Tokukaihei, No. 1-298623 (Publication Date: Dec. 1, 1989)

### SUMMARY OF INVENTION

### Technical Problem

However, among three examples of the production method disclosed in Patent Literature 1, in cases where an insulating film in which fine particles made of metal or the like are dispersed is produced by the method (1) or (2), it is difficult to control dispersion of the fine particles made of metal or the like in the insulating fine particles. This tends to cause aggregation of the fine particles. When the aggregation of the fine particles occurs, dielectric breakdown within the insulating film easily occurs. Meanwhile, according to the method (3), control of the dispersion of the fine particles is possible. However, because a plasma CVD apparatus or a thermal CVD apparatus is used, production cost drastically increases as compared with the other methods when an area is increased.

The present invention is attained in view of the above problems. An object of the present invention is to provide an electron emitting element (i) that makes dielectric breakdown hard to occur, (ii) that is produced easily at low cost, and (iii) that is capable of emitting a steady and sufficient amount of electrons.

### Solution to Problem

The inventors of the present application found, as a result of diligent studies for solving the above problems, that, even if fine particles made of metal or the like are not dispersed in an insulating layer, electron emission is made possible by a configuration in which an electron acceleration layer provided between electrodes includes insulating fine particles but does not include conductive fine particles. As a result, the inventors achieved the present invention.

In order to solve the problems mentioned above, an electron emitting element of the present invention includes: an electrode substrate; a thin-film electrode; and an electron acceleration layer that includes insulating fine particles but does not include conductive fine particles, the electron acceleration layer being provided between the electrode substrate and the thin-film electrode, the electron emitting element (i) accelerating electrons between the electrode substrate and the thin-film electrode at a time when a voltage is applied between the electrode substrate and the thin-film electrode and (ii) emitting the electrons from the thin-film electrode.

### ADVANTAGEOUS EFFECTS OF INVENTION

As described above, the electron emitting element of the present invention includes an electron acceleration layer that includes insulating fine particles but does not includes conductive fine particles between the electrode substrate and the thin-film electrode.

In a conventional MIM type or MIS type electron emitting element, it is difficult to form a thin even insulating film. When the insulating film has an uneven section in the insulating film, dielectric breakdown tends to occur. However, according to the electron emitting element of the present invention, the electron acceleration layer is configured to include insulating fine particles but not to include conductive fine particles. This configuration makes it possible to form an electron acceleration layer that does not require control of dispersion of the conductive fine particles and that does not have a section (e.g., aggregate) in which the dispersion of the conductive fine particles is not uniform. Therefore, dielectric breakdown is hard to occur in the electron emitting element of the present invention. Further, by an easy method in which an average particle diameter of the insulating fine particles and/or the number of accumulated insulating fine particles (film thickness of the electron acceleration layer) are/is controlled, the electron acceleration layer can be formed to be thicker than an electron acceleration layer of the conventional MIM or MIS type element. This makes it possible to easily provide an element capable of emitting a steady and sufficient amount of electrons. Furthermore, because the electron emitting element of the present invention is configured to include the insulating fine particles between the electrode substrate and the thin-film electrode, the electron acceleration layer can be easily formed. In addition, because the electron emitting element of the present invention does not include conductive fine particles, the electron emitting element can be produced at lower cost.

In the electron emitting element of the present invention, an electron emission characteristic can be controlled by an average particle diameter of the insulating fine particles and/or the number of accumulated insulating fine particles (film thickness of the electron acceleration layer). Though a voltage of approximately 100 V needs to be applied for causing the conventional MIS type element to emit a sufficient amount of electrons, the present electron emitting element emits the substantially same amount of electrons by application of approximately 20V.

An electron emission mechanism of the electron emitting element having the above configuration is considered to be similar to an operation mechanism of the so-called MIM type electron emitting element in which an insulating layer is inserted between two conductive films. Regarding a mechanism of formation of a current path at the time when an electric field is applied to an insulating layer in the MIM type electron emitting element, various explanations are provided as a general explanation. Examples of such explanations are: (a) diffusion of an electrode material into an insulating layer; (b) crystallization of the insulating material; (c) formation of a conductive path called filament; (d) variation in the insulating material in terms of stoichiometry; and (e) trapping of electrons due to a defect in the insulating material and an intense electric field region locally formed by the trapped electrons. However, the mechanism has not been determined yet. In any explanation, according to the above configuration of the present invention, the electrons are considered to be emitted to the outside of the element by (i) formation of the current path at the time when an electric field is applied to the electron acceleration layer made of a fine particle layer that includes insulating fine particles and that corresponds to an insulating layer, (ii) generation of ballistic electrons as a result of accelerating, by the electric field, a part of electrons in the current, and (iii) transmission of the ballistic electrons through the thin-film electrode that is one of the electrode substrate and the thin-film electrode that correspond to two conductive films.

In this way, the electron emitting element of the present invention makes dielectric breakdown hard to occur. Further, this electron emitting element is produced easily at low cost and capable of emitting a steady and sufficient amount of electrons.

### BRIEF DESCRIPTION OF DRAWINGS

FIG. 1 is a schematic view illustrating a configuration of an electron emitting device including an electron emitting element according to one embodiment of the present invention.

FIG. 2 is an enlarged view of the vicinity of an electron acceleration layer in the electron emitting element of the embodiment of the present invention.

FIG. 3 is a diagram illustrating an experiment system used in measurement of electron emission current.

FIG. 4 is a diagram illustrating an example of a charging device including an electron emitting device of the present invention.

FIG. 5 is a diagram illustrating an example of an electron-beam curing device including an electron emitting device of the present invention.

FIG. 6 is a diagram illustrating an example of a light emitting device including an electron emitting device of the present invention.

FIG. 7 is a diagram illustrating another example of a light emitting device including an electron emitting device of the present invention.

FIG. 8 is a diagram illustrating still another example of a light emitting device including an electron emitting device of the present invention.

FIG. 9 is a diagram illustrating an example of an image display device which includes a light emitting device including an electron emitting device of the present invention.

FIG. 10 is a diagram illustrating an example of an air blowing device including an electron emitting device of the present invention and a cooling device which includes the air blowing device.

FIG. 11 is a diagram illustrating another example of an air blowing device including an electron emitting device of the present invention and a cooling device which includes the air blowing device.

FIG. 12 is a photograph of a surface of an electron emitting element of a comparative example.

FIG. 13 is a diagram showing a result of measuring a current in element of the comparative electron emitting element.

FIG. 14(a) is a diagram showing an SEM observation image of an unbaked electron acceleration layer.

FIG. 14(b) is a diagram showing an SEM observation image of a baked electron acceleration layer.

### DESCRIPTION OF EMBODIMENTS

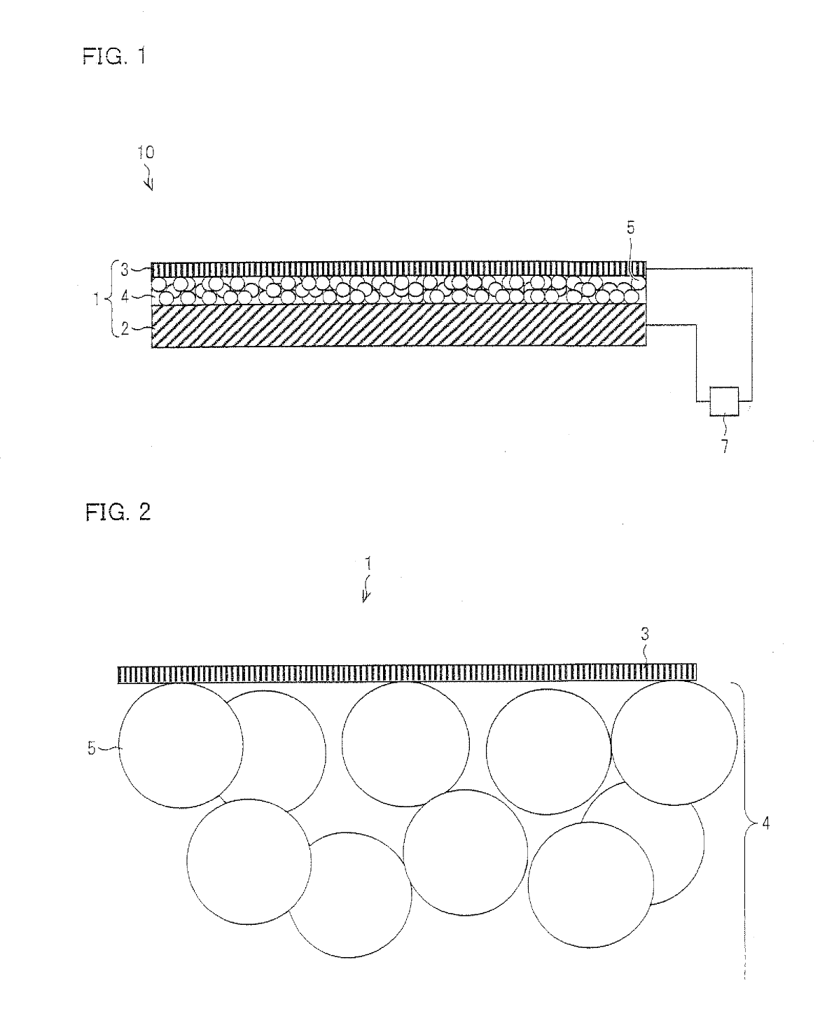

The following specifically explains Embodiments and Examples of an electron emitting element of the present invention, with reference to FIGS. 1 to 11. Note that Embodiments and Examples described below are merely specific examples of the present invention and by no means limit the present invention.

### Embodiment 1

FIG. 1 is a schematic view illustrating an embodiment of an electron emitting device including an electron emitting element of the present invention. As illustrated in FIG. 1, an electron emitting element 1 of the present embodiment includes an electrode substrate 2 serving as a lower electrode, a thin-film electrode 3 serving as an upper electrode, and an electron acceleration layer 4 sandwiched between the electrode substrate 2 and the thin-film electrode 3. Further, the electrode substrate 2 and the thin-film electrode 3 are connected to a power supply 7, so that a voltage can be applied between the electrode substrate 2 and the thin-film electrode 3 which are provided so as to face each other. The electron emitting element 1 applies a voltage between the electrode substrate 2 and the thin-film electrode 3 so that current flows between the electrode substrate 2 and the thin-film electrode 3, that is, in the electron acceleration layer 4. A part of electrons in the current are caused to transmit through the thin-film electrode 3 and/or be emitted through gaps in the thin-film electrode 3 as ballistic electrons due to an intense electric field formed by the applied voltage. The electron emitting element 1 and the power supply (power supply section) 7 constitute an electron emitting device 10.

The electrode substrate 2 serving as the lower electrode also acts as a supporting member of the electron emitting element. Accordingly, the electrode substrate 2 is not specifically limited in material as long as the material has a sufficient strength, excellent adhesiveness with respect to a substance in direct contact with the material and sufficient electrical conductivity. Examples of the electrode substrate include: metal substrates made of, for example, SUS, Ti, and Cu; semiconductor substrates made of, for example, Si, Ge, and GaAs; insulator substrates such as a glass substrate; and plastic substrates. In cases where an insulator substrate such as a glass substrate is used, an electrically conductive material such as metal is attached, as an electrode, to an interface of the insulator substrate and the electron acceleration layer 4 so that the insulator substrate can be used as the electrode substrate that serves as the lower electrode. A constituent material of the electrically conductive material is not specifically limited as long as a thin film of a material excellent in electric conductivity can be formed by magnetron sputtering or the like. Note that, if a steady operation of the electron emitting element in the atmosphere is desired, a conductor having a high resistance to oxidation is preferably used and noble metal is more preferably used for the constituent material. An ITO thin-film which is widely used as an electrically conductive oxide material for a transparent electrode is also applicable. Alternatively, it is possible to use, as the lower electrode, a metal thin film obtained by first forming a Ti film of 200 nm on a surface of a glass substrate and then forming a Cu film of 1000 nm on the Ti film, because a strong thin film can be formed. In this case, materials and values are not specifically limited to those described above.

The thin-film electrode 3 is for applying a voltage in the electron acceleration layer 4. Accordingly, a material of the thin-film electrode 3 is not specifically limited as long as the material makes it possible to apply a voltage. A material which has a low work function and from which a thin-film can be formed is expected to provide a greater effect, in view of emitting, with a minimum energy loss, electrons which have high energy due to acceleration within the electron acceleration layer 4. Examples of such a material include: gold, silver, carbon, tungsten, titanium, aluminum, and palladium each of which has a work function in a range of 4 eV to 5 eV. Among these materials, in particular, in consideration of an operation under an atmospheric pressure, the best material is gold which is free from oxide or sulfide formation reaction. Further, silver, palladium, or tungsten each of which has a relatively small oxide formation reaction is also applicable material that can be used without any problem.

Further, a film thickness of the thin-film electrode 3 is a very important factor for causing efficient emission of electrons from the electron emitting element 1 to the outside. The thin-film electrode 3 preferably has a film thickness in a range of 10 nm to 55 nm. The minimum film thickness of the thin-film electrode 3 is 10 nm, for causing the thin-film electrode 3 to work properly as a planar electrode. A film thickness of less than 10 nm cannot ensure electrical conduction. On the other hand, the maximum film thickness of the thin-film electrode 3 is 55 nm, for emitting electrons from the electron emitting element 1 to the outside. In a case where the film thickness is more than 55 nm, ballistic electrons do not pass thorough the thin-film electrode 3. In such a case, the ballistic electrons are absorbed by the thin-film electrode 3, or the ballistic electrons are reflected back by the thin-film electrode 3 and recaptured in the electron acceleration layer 4.

FIG. 2 is an enlarged view of the vicinity of the electron acceleration layer 4 of the electron emitting element 1. As shown in FIG. 2, the electron acceleration layer 4 is configured to include insulating fine particles 5 but not to include conductive fine particles.

A material of the insulating fine particles 5 is not specifically limited as long as the material has an insulating property. For example, SiO₂, Al₂O₃, and TiO₂ are practically used. However, in a case where surface-treated silica particles having a small particle diameter are used, a surface area of the surface-treated silica particles is increased in a dispersion solution (solution) and viscosity of the dispersion solution (solution viscosity) increases as compared to a case where spherical silica particles having a particle diameter larger than that of the surface-treated silica particles are used. As a result, a thickness of the electron acceleration layer 4 tends to increase slightly. Further, fine particles made of an organic polymer can be used as the material of the insulating fine particles 5. Examples of such fine particles that can be used are cross-linked fine particles (SX 8743) made of stylene/divinylbenzene manufactured and marketed by JSR Corporation, or Fine Sphere series which are styrene acryl fine particles manufactured and marketed by NIPPON PAINT Co., Ltd.

In the present embodiment, particles that may be used as the insulating fine particles 5 include (i) two or more different kinds of particles, (ii) particles having different peaks in diameter, or (iii) one kind of particles whose distribution of diameters is broad.

The insulating fine particles 5 have an average particle diameter preferably in a range of 7 nm to 400 nm. As explained later, a layer thickness of the electron acceleration layer 4 is preferably 1000 nm or less. However, when the average particle diameter of the insulating fine particles 5 becomes greater than 400 nm, it becomes difficult to control the layer thickness of the electron acceleration layer 4 so that the layer thickness becomes appropriate. Accordingly, the average particle diameter of the insulating fine particles 5 is preferably in the above range. In this case, distribution of the respective particle diameters may be broad with respect to the average particle diameter. For example, the respective particle diameters of the fine particles having an average particle diameter of 50 nm may be distributed in a range of 20 nm to 100 nm.

The insulating fine particles 5 may be surface-treated. The insulating fine particles 5 here may be surface-treated with silanol or a silyl group.

In production of the electron acceleration layer 4, when the insulting fine particles 5 are applied to the electrode substrate after the insulating fine particles 5 are dispersed in an organic solvent, dispersibility of the organic solvent improves in a case where respective particle surfaces are treated with silanol or a silyl group. As a result, it becomes easy to obtain the electron acceleration layer 4 in which the insulating fine particles 5 are evenly dispersed. Further, by dispersing the insulating fine particles 5 evenly, it becomes possible to form an electron acceleration layer that has a small layer thickness and a high surface smoothness. As a result, the thin-film electrode 3 on the electron acceleration layer 4 can be formed thinly. As described above, the thinner the film thickness of the thin-film electrode 3 which can ensure electric conductivity becomes, the more efficiently the electrons can be emitted.

As a surface-treatment method with the use of silanol or a silyl group for the insulating fine particles, there are a dry method and a wet method.

In the dry method, for example, while the insulating fine particles are stirred vigorously in a stirring machine, a silane compound or a diluted solution of the silane compound is dropped on the insulating fine particles or sprayed on the insulating fine particles by using a spray or the like, and then the silane compound or the diluted solution is dried by heat. As a result, targeted insulating fine particles that are surface-treated can be obtained.

In the wet method, for example, a solvent is added to the insulating fine particles so that the insulating fine particles in a state of sol are obtained. Then, a silane compound or a diluted solution of the silane compound is added and the surface treatment is carried out. Subsequently, the solvent is removed from the sol of the fine particles that have been surface-treated as described above, and then the fine particles are dried and sheaved. As a result, targeted surface-treated insulating fine particles are obtained. The surface-treated insulating fine particles obtained as described above may be further surface-treated.

The silane compound may be a compound represented by a chemical structural formula: RaSiX₄₋ₐ (where: a is an integer of 0 to 3; R is a hydrogen atom, or an organic group such as an alkyl group or an alkenyl group; X is a chlorine atom or a hydrolysable group such as a methoxy group or a ethoxy group). It is possible to use any of chlorosilane, alkoxysilane, silazane, and any type of special silylation agents.

Specifically, typical examples of the silane compounds are: methyltrichlorosilane, dimethyldichlorosilane, trimethylchlorosilane, phenyltrichloro silane, diphenyldichlorosilane, tetramethoxysilane, methyltrimethoxysilane, dimethyldimethoxysilane, phenyltrimethoxysilane, diphenyldimethoxysilane, tetraethoxysilane, methyltriethoxysilane, dimethyldiethoxysilane, phenyltriethoxysilane, diphenyldiethoxysilane, isobutyltrimethoxysilane, decyltrimethoxysilane, hexamethyldisilazane, N,O-bis(trimethylsilyl)acetamide, N,N′-bis(trimethylsilyl)urea, tert-butyldimethylchlorosilane, vinyltrichlorosilane, vinyltrimethoxysilane, vinyltriethoxysilane, γ-methacryloxypropyltrimethoxysilane, β-(3,4-epoxycyclohexyl)ethyltrimethoxysilane, γ-glycidoxypropyltrimethoxysilane, γ-glycidoxypropylmethyldiethoxysilane, γ-mercaptopropyltrimethoxysilane, γ-chloropropyltrimethoxysilane. In particular, dimethyldimethoxysilane, hexamethyldisilazane, methyltrimethoxysilane, dimethyldichlorosilane and the like are preferable.

Further, other than the silane compound, silicone oil such as dimethyl silicone oil and methyl hydrogen silicone oil may be used.

A layer thickness of the electron acceleration layer 4 is not less than an average particle diameter of the insulating fine particles and preferably 1000 nm or less. The smaller the layer thickness of the electron acceleration layer 4 becomes, the more easily the current flows. However, the layer thickness is the smallest when the insulating fine particles 5 of the electron acceleration layer 4 are evenly placed as one layer on the electrode substrate so that the insulating fine particles 5 do not overlap with each other (each insulating fine particle 5 is not provided on top of another). Therefore, the minimum layer thickness of the electron acceleration layer 4 is an average particle diameter of the insulating fine particles 5 forming the electron acceleration layer 4. A case where the layer thickness of the electron acceleration layer 4 is smaller than the average particle diameter of the insulating fine particles 5 means a state in which the electron acceleration layer 4 includes a section where the insulating fine particles 5 is not present. In such a case, the electron acceleration layer 4 does not function as an electron acceleration layer. Therefore, the average particle diameter is preferable as the lowest limit value of the layer thickness of the electron acceleration layer 4. The lowest limit value of the layer thickness of the electron acceleration layer 4 is considered to be more preferably a layer thickness in a case where two or more insulating fine particles 5 are accumulated. This is because, in a case where the electron acceleration layer 4 has the layer thickness equal to a diameter of one constituent particle, leak current increases though an amount of current flowing in the electron acceleration layer 4 increases. This weakens the intensity of the electric field exerted on the electron acceleration layer. As a result, electrons cannot be emitted efficiently. Meanwhile, in a case where the layer thickness is more than 1000 nm, a resistance of the electron acceleration layer increases and a sufficient current does not flow. As a result, a sufficient amount of electrons cannot be emitted.

Note that, though the layer thickness of the electron acceleration layer 4 is controlled by the particle diameter of the insulating fine particles 5 and a concentration (viscosity) of a dispersion solution in which the insulating fine particles 5 are dispersed in a solvent, the layer thickness is greatly influenced particularly by the concentration.

Further, a surface roughness of the electron acceleration layer 4 is preferably 0.2 μm or less in center line average roughness (Ra). Further, a film thickness of the thin-film electrode is preferably 100 nm or less.

As described later, in a case where the thin-film electrode 3 is formed on the electron acceleration layer 4 by sputtering, the thin-film electrode 3 becomes thin on a depressed section of the electron acceleration layer 4 and thick on a bulging section of the electron acceleration layer 4. In such a case, conductivity on a surface cannot be ensured because unevenness of the surface is emphasized and the surface becomes like an island in the case of the thin-film electrode having a small film thickness. For absorbing the unevenness of the surface of the electron acceleration layer 4 so that the conductivity on the surface of the thin-film electrode 3 can be ensured, the film thickness of the thin-film electrode 3 needs to be increased. That is, the electrode needs to be formed so as to be thicker than the electrode that is formed on a flat surface. Accordingly, the rougher the surface of the electron acceleration 4 becomes, the thicker the thin-film electrode 3 needs to be. However, when the film thickness of the thin-film electrode 3 is increased, the amount of electrons emitted through the thin-film electrode decreases and the amount of electrons emitted decreases.

However, when the surface roughness of the electron acceleration layer 4 is optimized so that the center line average roughness (Ra) is 0.2 μm or less, the thickness of the thin-film electrode 3 can be reduced to an appropriate thickness of 100 nm or less. When the thin-film electrode 3 becomes too thick, the amount of electrons emitted through the thin-film electrode 3 decreases though the conductivity on the surface of the element is ensured. Therefore, the thickness of the thin-film electrode 3 is preferably 100 nm or less.

As described above, in the electron emitting element 1, the electron acceleration layer 4 includes the insulating fine particles 5 but does not include conductive fine particles.

In a conventional MIM type or MIS type electron emitting element, it is difficult to form a thin even insulating film. Moreover, dielectric breakdown tends to occur when the insulating film has an uneven section. However, according to the electron emitting element 1, as described above, the electron acceleration layer 4 includes the insulating fine particles 5 but does not include conductive fine particles. This configuration makes it possible to form an electron acceleration layer that does not require control of dispersion of conductive fine particles and that does not have a section (e.g., aggregate) in which the dispersion of the conductive fine particles is not uniform. Therefore, dielectric breakdown is hard to occur. Further, by an easy method in which an average particle diameter of the insulating fine particles and/or the number of accumulated insulating fine particles (film thickness of the electron acceleration layer) are/is controlled, it becomes possible to form an electron acceleration layer that is thicker than an electron acceleration layer of the conventional MIM or MIS type element. This makes it possible to easily provide an element capable of emitting a steady and sufficient amount of electrons. Furthermore, because the electron emitting element of the present invention is configured to include the insulating fine particles 5 between the electrode substrate 2 and the thin-film electrode 3, the electron acceleration layer can be easily formed. In addition, because the electron emitting element 1 does not include conductive fine particles, the electron emitting element 1 can be produced at lower cost.

In the electron emitting element 1 of the present embodiment, an electron emission characteristic can be controlled by controlling the average particle diameter of the insulating fine particles 5 and/or the number of accumulated insulating fine particles 5 (layer thickness of the electron acceleration layer 4). Though a voltage of approximately 100 V needs to be applied for causing the conventional MIS type element to emit a sufficient amount of electrons, the present electron emitting element 1 emits the substantially same amount of electrons by application of approximately 20V.

Next, an electron emission mechanism of the electron emitting element 1 of the present embodiment is explained. Though the electron emission mechanism of the electron emitting element 1 is not clearly determined, the following explanation is possible by using an explanation (e) among five explanations (a) to (e) on a mechanism of formation of a conductive path as explained above. That is, when a voltage is applied between the electrode substrate 2 and the thin-film electrode 3, electrons move to respective surfaces of the insulating fine particles 5 form the electrode substrate 2. Because the inside of each of the insulating fine particles 5 has a high resistance, the electrons are conducted on the surface of the insulating fine particles 5. During the conduction, the electrons are trapped in an impurity on the surface of the insulating fine particles 5 or an oxygen-depleted section that occurs in a case where the insulating fine particles 5 are oxide, or at a contact between the insulating fine particles 5. The electrons trapped as described above work as fixed electric charge. As a result, an intense electric field region is produced locally in the vicinity of the thin-film electrode 3 of the electron acceleration layer 4 due to a combination of electric fields formed by an applied voltage and the electrons trapped. Due to the intense electric field, the electrons are accelerated. Consequently, the electrons are emitted from the thin-film electrode 3.

Note that the power supply 7 may apply a DC voltage (direct current voltage) between the electrode substrate 2 and the thin-film electrode 3.

As described above, the electron emitting element 1 makes dielectric breakdown hard to occur. Further, the electron emitting element 1 is produced easily at low cost, and capable of emitting a steady and sufficient amount of electrons.

Note that the electron emitting element 1 may be configured such that a basic dispersion agent is discretely provided on the electron acceleration layer 4 that includes the insulating fine particles 5 but does not include conductive fine particles. When the basic dispersion agent is discretely provided on the electron acceleration layer 4 that includes the insulating fine particle 5 but does not include conductive fine particles, a section where the basic dispersion agent is discretely provided becomes an electron emitting section. Accordingly, the electron emitting element 1 in which the basic dispersion agent is discretely provided is an element in which the electron emitting section is patterned. Therefore, it becomes possible to control a position of the electron emitting section and prevent a phenomenon in which a constituent material of the thin-film electrode that is formed on the electron acceleration layer 4 is worn out by the electrons emitted. Further, the amount of electrons emitted from each electron emitting section can be independently controlled.

The following explanation deals with a method for forming the electron emitting element 1. First, a dispersion solution in which the insulating fine particles 5 are dispersed in a solvent is obtained (dispersion step, step of obtaining a dispersion solution). The solvent that is used here is not specifically limited as long as the insulating fine particles 5 are dispersed in the solvent and dried after application of the dispersion solution. Examples of such a solvent are: toluene, benzene, xylene, hexane, methanol, ethanol, and propanol.

Then, the dispersion solution of the insulating fine particles 5 prepared as described above is applied on the electrode substrate 2 by using a spin coating method (application step, step of applying the dispersion solution) so as to form the electron acceleration layer 4 (electron acceleration formation step, step of forming the electron acceleration layer). By repeating the formation by the spin coating method and drying (drying step, step of drying) a plurality of times, a predetermined layer thickness can be obtained. The electron acceleration layer can be formed by, for example, a dropping method or a spray coating method, other than the spin coating method.

After the formation of the electron acceleration layer 4, the thin-film electrode 3 is formed on the electron acceleration layer 4 (thin-film electrode formation step, step of forming the thin-film electrode). For formation of the thin-film electrode 3, for example, a magnetron sputtering method may be used. Alternatively, the thin-film electrode 3 can be formed by, for example, an ink-jet method, a spin coating method, or a vapor deposition method.

Here, the electron emitting element may be baked (baking step, step of baking) after the electron acceleration layer formation step or the thin-film electrode formation step. By baking the electron emitting element, a crack is formed in the electron acceleration layer 4. This makes it possible to obtain the electron emitting element 1 that emits a large amount of electrons.

Conditions of the baking depend on the particle diameter of the insulating fine particles 5. Preferable time and temperature conditions are titre and temperature that do not melt the insulating fine particles 5 completely. For example, in a case where the insulating fine particles 5 are made of SiO₂, the temperature is preferably in a range of 100° C. to 1000° C. The smaller the particle diameter of the insulating fine particles 5 is, the lower the temperature at which the insulating fine particles 5 completely melt becomes and accordingly the lower the desirable temperature for baking becomes.

If the insulating fine particles 5 completely melt, the insulating fine particles 5 become an insulating film and do not serve as an electron acceleration layer.

The baking step may be performed either before or after the thin-film electrode 3 is formed on the electron acceleration layer 4. However, in a case where the baking step is performed after the formation of the thin-film electrode 3, a high baking temperature may cause the thin-film electrode 3 to peel off the electron acceleration layer 4 and consequently the electron emitting element 1 may not properly function as an electron emitting element.

The temperature at which the thin-film electrode 3 peels off the electron acceleration layer 4 depends on thermal expansion coefficients of respective materials of the insulating fine particles 5 and the thin-film electrode 3. The greater a difference between the thermal expansion coefficients becomes, the more easily the peeling occurs in the baking. Therefore, it is preferable to form the thin-film electrode 3 after the baking.

Though a mechanism in which the amount of electrons emitted is increased by the baking has not been determined, the following is considered as the mechanism.

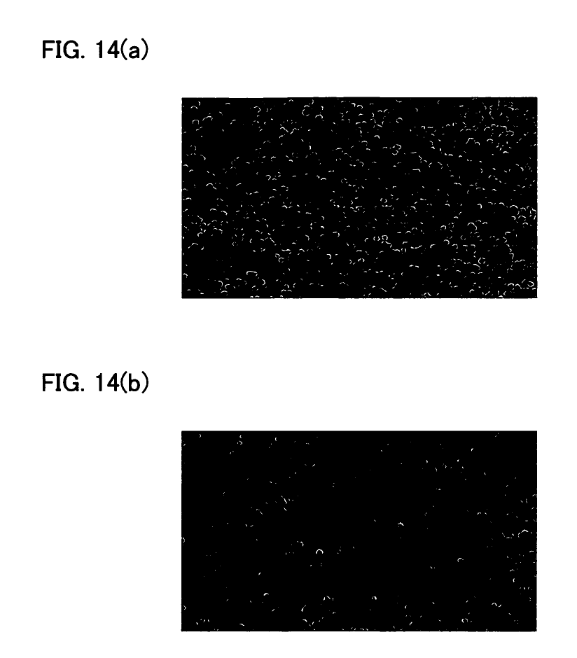

By baking the electron emitting element, thermal expansion of the insulating fine particles 5 occurs and a crack is produced in the electron acceleration layer 4 due to distortion that results from joining of the insulating fine particles 5. This crack is considered to make it easy to emit the electrons and accordingly to increase the amount of electrons emitted. FIG. 14(a) shows an SEM observation image of the electron acceleration layer 4 before the baking, and FIG. 14(b) shows an SEM observation image of the electron acceleration layer after the baking. In these SEM observation images are images of the electron acceleration layer 4 in the electron emitting element of Example 7 described later. It is clear from these images that cracks are produced in the electron acceleration layer 4 by baking the electron emitting element.

The electron emitting element 1 is produced as described above.

### EXAMPLE

The following examples explain experiments in each of which current was measured by using the electron emitting element of the present invention. Note that the experiments are merely examples of the embodiment and by no means limit the present invention.

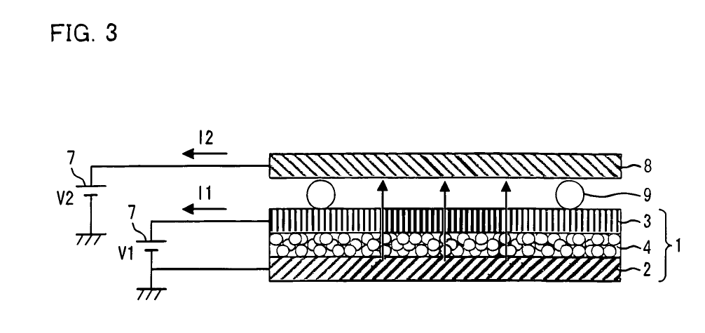

First, electron emitting elements of Examples 1 to 5 and Comparative Example 1 were produced as described below. Then, an experiment was carried out on each of the electron emitting elements of Examples 1 to 4 and Comparative Example 1. In the experiment, electron emission current per unit area was measured by using an experiment system as shown in FIG. 3. In the experiment system of FIG. 3, a counter electrode 8 was provided on a side of the thin-film electrode 3 of the electron emitting element 1 so that the counter electrode 8 and the thin-film electrode 3 sandwiched an insulating spacer 9. Each of the electron emitting element 1 and the counter electrode 8 was connected to a power supply 7 so that a voltage V1 was applied to the electron emitting element 1 and a voltage V2 was applied to the counter electrode 8. The above experiment system was set up in vacuum. Then, an electron emission experiment was carried out while V1 was increased gradually. Further, in the experiment, a distance via the insulating spacer 9 between the electron emitting element and the counter electrode was set to 5 mm. The voltage V2 applied to the counter electrode was 100V.

### Example 1

First, four reagent bottles in which 3 mL of ethanol was supplied as a solvent were prepared. Then, 0.15 g, 0.25 g, 0.35 g, 0.50 g of silica particles (average particle diameter: 110 nm, specific surface area: 30 m²/g) which were surface-treated with hexamethyldisilazane (HMDS) were added as the insulating fine particles 5 to the four reagent bottles, respectively. Subsequently, each of the reagent bottle was set in an ultrasonic dispersion device so that silica particle dispersion solutions A, B, C, and D each having a different concentration were produced.

Next, four 25-mm square SUS substrates were prepared as the electrode substrates 2. On the respective SUS substrates, the silica particle dispersion solutions A, B, C, and D were dropped and respective electron acceleration layers A, B, C, and D were formed by the spin coating method. A condition of the film formation by the spin coating method was such that (i) first the silica particle dispersion solutions A, B, C, and D were dropped on substrate surfaces, respectively, while the substrates were spun at 500 rpm for 5 seconds and (ii) then the substrates on which the silica particle dispersion solutions A, B, C, and D were dropped, respectively, were spun at 3000 rpm for 10 seconds. The film formation under this condition was repeated twice and two fine particle layers were deposited on each of the substrates. Then, the fine particle layers were dried at a room temperature.

On each of the surfaces of the electron acceleration layers A, B, C, and D, the thin-film electrode 3 was formed by using a magnetron sputtering device, so that electron emitting elements A, B, C, and D of Example 1 were obtained. Gold was used as a material for forming the thin-film electrode 3. A thickness of the thin-film electrode 3 was 40 nm and an area thereof was 0.014 cm².

A thickness of the electron acceleration layer of each of the electron emitting elements A, B, C, and D was measured by using a laser microscope (VK-9500, manufactured by Keyence Corporation). Further, electron emitting current of each of the electron emitting elements A, B, C, and D was measured.

In the electron emitting element A, a layer thickness of the electron acceleration layer 4 was 0.2. As a result of measuring the electron emission current in vacuum at 1×10⁻⁸ ATM, the electron emission current was 3.5×10⁻⁴ mA/cm² when the voltage V1 of 12 V was applied to the thin-film electrode 3. Regarding this element A, electron emission stopped when the voltage V1 was 13V or more. Though a reason for this was not determined, it was considered that the reason was such that much leak current was produced due to a small layer thickness of the electron acceleration layer.

In the electron emitting element B, a layer thickness of the electron acceleration layer 4 was 0.3 μm. As a result of measuring the electron emission current in vacuum at 1×10⁻⁸ ATM, the electron emission current was 0.1 mA/cm² when the voltage V1 of 25 V was applied to the thin-film electrode 3.

In the electron emitting element C, a layer thickness of the electron acceleration layer 4 was 0.4 μm. As a result of measuring the electron emission current in vacuum at 1×10⁻⁸ ATM, the electron emission current was 1.0×10⁻² mA/cm² when the voltage V1 of 20 V was applied to the thin-film electrode 3.

In the electron emitting element D, a layer thickness of the electron acceleration layer 4 was 0.8 μm. As a result of measuring the electron emission current in vacuum at 1×10⁻⁸ ATM, the electron emission current was 4.3×10⁻³ mA/cm² when the voltage V1 of 15 V was applied to the thin-film electrode 3.

Note that 30 thin film electrodes 3 of 1 mm×1.4 mm were formed on respective 25 mm square SUS substrates, that is, 30 electron emitting elements were produced, and electron emission current was measured.

### Example 2

First, four reagent bottles were prepared. Into the four reagent bottles, respectively supplied were (i) 0.15 g of silica particles having a particle diameter of 12 nm (specific surface area: 200 m²/g), (ii) 0.15 g of DDS-treated particles obtained by treating, with dimethyldichlorosilane (DDS), surfaces of the silica particles having an average particle diameter of 12 nm, (iii) 0.15 g of HMDS-treated particles obtained by treating, with hexamethyldisilazane (HMDS), the surfaces of the silica particles having an average particle diameter of 12 nm, and (iv) 0.15 g of silicone-oil-treated particles obtained by treating, with silicone oil, the surfaces of the silica particles having an average particle diameter of 12 nm. Then, 0.6 mL of ethanol as a solvent was added to each of the reagent bottles. Subsequently, each of the reagent bottles was set in an ultrasonic dispersion device so that silica particle dispersion solutions E, F, G, and H were produced.

By using the silica particle dispersion solutions E, F, G, and H, electron emitting elements E, F, G, and H of Example 2 were produced in the same manner as in Example 1.

A thickness of the electron acceleration layer of each of the electron emitting elements E, F, G, and H was measured by using a laser microscope (VK-9500, manufactured by Keyence Corporation). As a result, the electron emitting element E had a layer thickness of 0.6 μm to 1.2 μm; the electron emitting element F had a layer thickness of 0.8 μm; the electron emitting element G had a layer thickness of 0.7 μm; and the electron emitting element H had a layer thickness of 1.4 μm. Regarding the layer thickness of the electron acceleration layer in the electron emitting element E, a thick section and a thin section were present.

Table 1 shows a result of measuring electron emission current of the electron emitting elements E, F, G, and H in vacuum at 1×10⁻⁸ ATM.

TABLE 1

| | Electron Emitting Element | | | |
|---|---|---|---|---|
| | E | F | G | H |
| Surface | None | DDS | HMDS | Silicone |
| Treating Agent | | | | Oil |
| Applied | 20 | 15 | 15 | 18 |
| Voltage (V) | | | | |
| Electron | 4.0 × 10⁻⁵ | 1.3 × 10⁻⁴ | 7.5 × 10⁻⁴ | 3.2 × 10⁻⁵ |
| Emission | | | | |
| Current | | | | |
| (mA/cm²) | | | | |

### Example 3

First, 3 mL of ethanol was supplied as a solvent into a regent bottle. Then, 0.06 g of silica particles (average particle diameter: 7 nm, specific surface area: 300 m²/g) which were surface-treated with dimethyldichlorosilane (DDS) were added. The reagent bottles was then set in an ultrasonic dispersion device so that a silica particle dispersion solution I was produced.

By using this silica particle dispersion solution I, an electron emitting element I of Example 3 was produced in the same manner as in Example 1. A layer thickness of the electron acceleration layer of this electron emitting element I was measured by using a laser microscope (VK-9500, manufactured by Keyence Corporation). As a result, the layer thickness was 0.5 μm. Further, the electron emitting element 1 was set in vacuum at 1×10⁻⁸ ATM and electron emission current was measured. As a result, the electron emission current was 3.2×10⁻³ mA/cm² when the voltage V1 of 15 V was applied to the thin-film electrode 3.

### Example 4

First, 3 mL of ethanol was supplied as a solvent into a regent bottle. Then, 0.25 g of silica particles (average particle diameter: 200 nm, specific surface area: 30 m²/g) which were surface-treated with hexamethyldisilazane (HMDS) were added. The reagent bottle was then set in an ultrasonic dispersion device so that a silica particle dispersion solution J was produced.

By using this silica particle dispersion solution J, an electron emitting element J of Example 4 was produced in the same manner as in Example 1. A layer thickness of the electron acceleration layer of this electron emitting element J was measured by using a laser microscope (VK-9500, manufactured by Keyence Corporation). As a result, the layer thickness was 0.4 μm. Further, the electron emitting element J was set in vacuum at 1×10⁻⁸ ATM and electron emission current was measured. As a result, the electron emission current was 0.3 mA/cm² when the voltage V1 of 15 V was applied to the thin-film electrode 3.

### Example 5

First, 3 mL of toluene was supplied as a solvent into a regent bottle. Then, 0.15 g of silicone resin fine particles (manufactured by Momentive Performance Materials (Japan) Inc., TOSPEARL, average particle diameter: 0.7 μm) were added as the insulating fine particles 5. The reagent bottle was then set in an ultrasonic dispersion device so that the silicone fine particles were dispersed. As a result, a silicone fine particle dispersion solution K was produced.

By using this silicone fine particle dispersion solution K, an electron acceleration layer K was formed on a 25-mm square SUS substrate as the electrode substrate 2 in the same manner as in Example 1 by a spin coating method. Then, on a surface of the electron acceleration layer K, the thin-film electrode was formed by a magnetron sputtering device. As a result, an electron emitting element K of Example 5 was obtained. Gold was used as a material for forming the thin-film electrode 3. A thickness of the thin-film electrode 3 was 70 nm and an area thereof was 0.014 cm².

A thickness of the electron acceleration layer of the electron emitting element K was measured by using a laser microscope (VK-9500, manufactured by Keyence Corporation). As a result, the layer thickness was 1.0 μm.

The electron emitting element K was set in vacuum at 1×10⁻⁸ ATM and electron emission current was measured. As a result, the electron emission current was 4.0×10⁻⁶ mA/cm² when the voltage V1 of 20 V was applied to the thin-film electrode 3.

### Example 6

First, 3 mL of ethanol was supplied as a solvent into a regent bottle. Then, 0.25 g of silica particles (average particle diameter: 110 nm, specific surface area: 30 m²/g) which were surface-treated with hexamethyldisilazane (HMDS) were added to the toluene as the insulating fine particles 5. Subsequently, the reagent bottle was set in an ultrasonic dispersion device so that a silica particle dispersion solution L was produced.

Next, a 25-mm square SUS substrate was prepared as the electrode substrate 2. On the SUS substrate, the silica particle dispersion solution L was dropped and an electron acceleration layer was formed by a spin coating method. A condition of the film formation by the spin coating method was such that (i) first the silica particle dispersion solution L was dropped on a substrate surface, while the substrate was spun at 500 rpm for 5 seconds and (ii) then the substrate on which the silica particle dispersion solution L was dropped was spun at 3000 rpm for 10 seconds. The film formation under the condition was repeated twice and two layers of the electron acceleration layer were deposited on the SUS substrate. Then, the layers were dried at a room temperature. Subsequently, the electrode substrate on which the electron acceleration layer was formed was baked at 300° C. for one hour in an electric furnace.

After the baking, on a surface of the electron acceleration layer, the thin-film electrode 3 was formed by using a magnetron sputtering device, so that the electron emitting element of Example 6 was obtained. Gold was used as a material for forming the thin-film electrode 3. A thickness of the thin-film electrode 3 was 40 nm and an area thereof was 0.01 cm².

The electron emitting element of Example 6 was set in vacuum at 1×10⁻⁸ ATM and electron emission current was measured. As a result, the electron emission current was 2.3×10⁻¹ mA/cm² when the voltage V1 of 20 V was applied to the thin-film electrode 3.

### Example 7

An electron emitting element of Example 7 was produced in the same manner as in Example 6 except that the conditions of the baking with the use of the electric furnace were changed to 300° C. for one hour and the thin-film electrode 3 was formed before the baking.

The electron emitting element of Example 7 was set in vacuum at 1×10⁻⁸ ATM and electron emission current was measured. As a result, the electron emission current was 3.6×10⁻² mA/cm² when the voltage V1 of 20 V was applied to the thin-film electrode 3.

### Example 8

An electron emitting element of Example 8 was produced in the same manner as in Example 6 except that the conditions of the baking with the use of the electric furnace were changed to 600° C. for one hour.

The electron emitting element of Example 8 was set in vacuum at 1×10⁻⁸ ATM and electron emission current was measured. As a result, the electron emission current was 6.5×10⁻² mA/cm² when the voltage V1 of 20 V was applied to the thin-film electrode 3.

Further, electron emission current of the electron emitting element of Example 8 in the atmosphere was measured by using a setting such that: (i) the voltage V1 applied to the thin-film electrode 3 was 25V, (ii) the voltage V2 applied to the counter electrode was 200V, and (iii) a distance between the electron acceleration layer and the counter electrode was 1 mm. In this case, the electron emission current was 4.9×10⁻⁵ mA/cm².

Note that in an electron emitting element baked after formation of the thin-film electrode 3 under the same condition as in Example 8, peeling of the thin-film electrode 3 was observed. In such a case, no current flow was produced when a voltage was applied between the electrode substrate 2 and the thin-film electrode 3, and no electron emission was observed.

### Comparative Example 1

First, 3 g of toluene was supplied as a solvent into a 10 mL regent bottle. Then, 0.25 g of silica fine particles (fumed silica C413 (manufactured by Cabot Corporation), having a particle diameter of 50 nm and surface-treated with hexamethyldisilazane were added as the insulating fine particles 5 to the toluene. Subsequently, the reagent bottle was set in an ultrasonic dispersion device. After approximately 10 minutes of ultrasonic dispersion, 0.065 g of silver nanoparticles (average particle diameter: 10 nm (inclusive of a thickness of 1 nm of an alcoholate insulating coating film), manufactured by Applied Nanoparticle Laboratory Co.) were further added. Then, an ultrasonic dispersion processing was further carried out for approximately 20 minutes so that an insulating fine particle/conductive fine particle dispersion solution was produced. A ratio of the silver nanoparticles with respect to a total mass of the silica fine particles was approximately 20%.

Next, a 30-mm square SUS substrate was prepared as the electrode substrate 2. On a surface of the SUS substrate, the insulating fine particle/conductive fine particle dispersion solution was dropped and an electron acceleration layer was formed by a spin coating method. A condition of the film formation by the spin coating method was such that (i) first the insulating fine particle/conductive fine particle dispersion solution was dropped on the substrate surface, while the substrate was spun at 500 rpm for 5 seconds and (ii) then the substrate on which the insulating fine particle/conductive fine particle dispersion solution was dropped was spun at 3000 rpm for 10 seconds. The film formation under the condition was repeated twice and two fine particle layers were deposited on the SUS substrate. Then, the fine particle layers were dried at a room temperature.

After the electron acceleration layer was formed on the surface of the SUS substrate, the thin-film electrode 3 was formed by using a magnetron sputtering device. Gold was used as a material for forming the thin-film electrode 3. A thickness of the thin-film electrode 3 was 45 nm and an area thereof was 0.071 cm². This area of the thin-film electrode 3 had a circular shape. In this way, an electron emitting element of Comparative Example 1 that includes the conductive fine particles in the electron acceleration layer 4 was obtained.

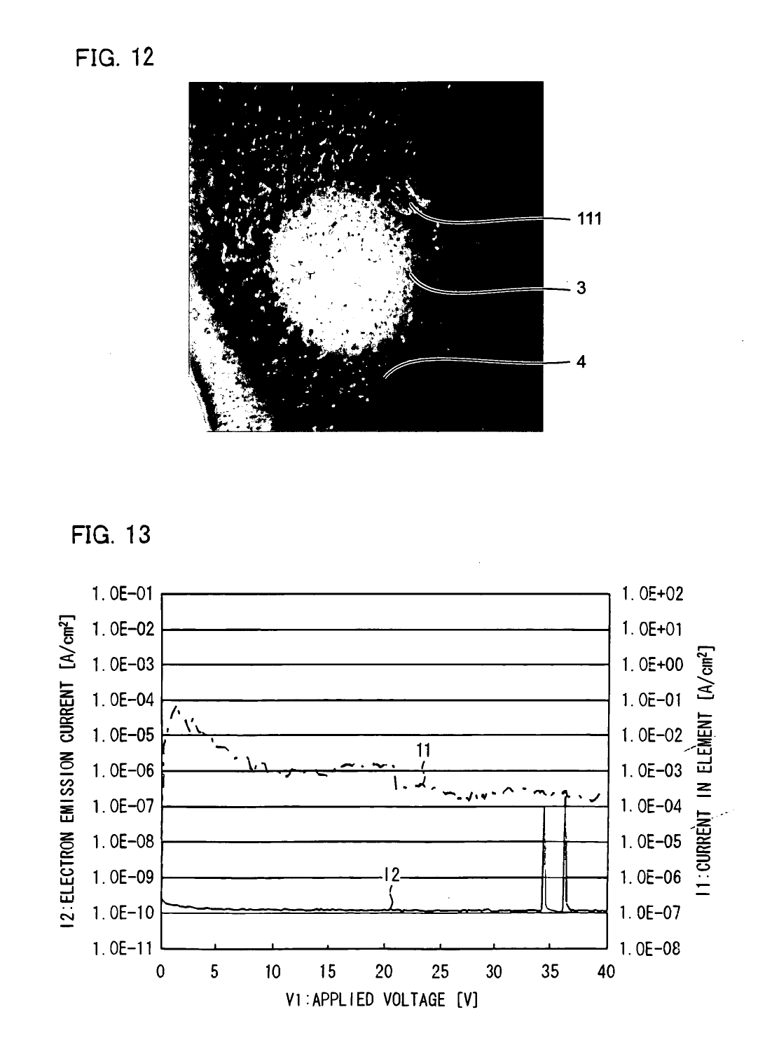

FIG. 12 shows a photograph of a surface of the electron emitting element of Comparative Example 1. A circular section in FIG. 12 is the thin-film electrode and a ring-shaped section is a surface of the electron acceleration layer 4 on which the thin-film electrode 3 is not provided. Further, a member indicated by the reference sign 111 is a contact probe that comes into contact with the thin-film electrode 3 for applying a voltage. It is clear from FIG. 12 that a surface of the electron emitting element of Comparative Example 1 is coarse.

The electron emission experiment was carried out on the electron emitting element of Comparative Example 1 that was produced as described above, by using the experiment system as shown in FIG. 3.

FIG. 13 shows a result of measuring current I1 in element of the electron emitting element of Comparative Example 1 and a result of measuring electron emission current I2 that is emitted from the electron emitting element. The applied voltage V1 was gradually increased in a range from 0V to 40V. The applied voltage V2 was set to 100V.

As shown in FIG. 13, a sufficient amount of the current I1 in element cannot flow in the electron emitting element of Comparative Example 1. The reason for this is considered as follows: (i) because the surface of the element becomes coarse due to reaggregation of fine particles, the electron acceleration layer cannot maintain a sufficiently conductive state; and (ii) an electrically conductive characteristic in the fine particle layer constituting the electron acceleration layer deteriorates mainly due to aggregation of silver fine particles.

Further, a spike-like electron emission current I2 was observed at the applied voltage V1 of approximately 35V. This is because electric charge accumulated in the insulating fine particles constituting the electron acceleration layer causes dielectric breakdown at one go. When such a waveshape occurs, the electron acceleration layer is physically broken down. In this way, in an element in which a dispersion state of the conductive fine particles is poor, the electric breakdown easily occurs in the fine particle layer constituting the electron acceleration layer.

It is clear from these examples and comparative example that a steady and sufficient amount of electrons can be emitted if the electron acceleration layer is configured to include insulating fine particles but not to include conductive fine particles.

Note that it is considered from examination of a result of Example 2 that the following points (1) to (3) are possible.

(1) When insulating fine particles that are not surface-treated are used, a dispersion state of the insulating fine particles in the electron acceleration layer becomes poor. That is, the insulating fine particles are not evenly dispersed, so that an aggregate of the insulating fine particles is present. When such an aggregate of the insulating fine particles is present, a gap between the insulating fine particles increases and a resistance of the electron acceleration layer becomes higher as compared with an electron acceleration layer in which the insulating fine particles are finely and evenly dispersed.

(2) When the insulating fine particles that are not surface-treated are used, a dispersion state of the insulating fine particles in the electron acceleration layer becomes poor. That is, the insulating fine particles are not evenly dispersed, so that an aggregate of the insulating fine particles is present. When such an aggregate of the insulating fine particles is present, (i) a layer thickness of the electron acceleration layer becomes thicker as compared with that of an electron acceleration layer in which the insulating fine particles are evenly dispersed and a thin section and (ii) a thick section are produced in the electron acceleration layer. Because the thin section has a low resistance and the thick section has a high resistance, a resistance of the electron acceleration layer becomes high.

(3) When the insulating fine particles that are surface-treated are used, it is highly likely that a surface treating agent functions like conductive fine particles or a basic dispersion agent and contributes to acceleration of electron transfer. However, when the insulating fine particles that are not surface-treated are used, a phenomenon of the acceleration of electron transfer is not produced by the surface treating agent and accordingly a resistance of the electron acceleration layer becomes high.

### Embodiment 2

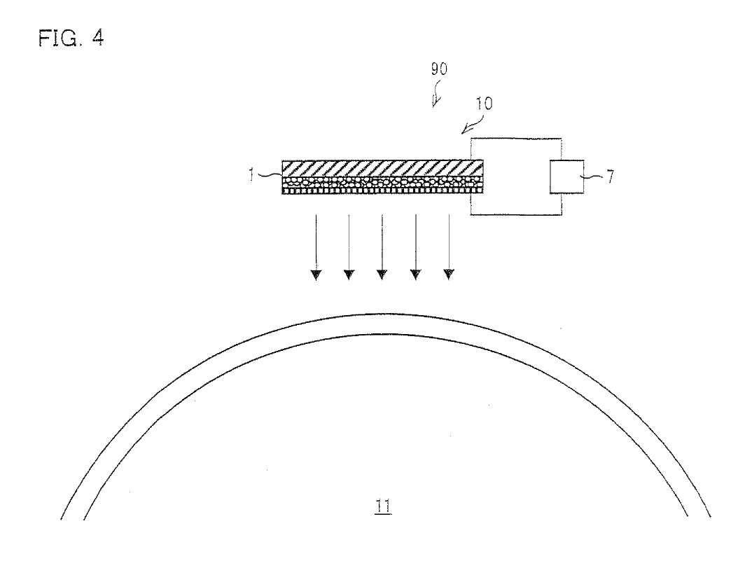

FIG. 4 shows an example of a charging device 90 of the present invention including an electron emitting device 10 including an electron emitting element 1 described in Embodiment 1.

The charging device 90 includes the electron emitting device 10 including the electron emitting element 1 and a power supply 7 for applying a voltage to the electron emitting element 1. The charging device 90 is used for electrically charging a photoreceptor 11. An image forming apparatus of the present invention includes the charging device 90. In the image forming apparatus of the present invention, the electron emitting element 1 in the charging device 90 is provided so as to face the photoreceptor 11 to be charged. Application of a voltage causes the electron emitting element 1 to emit electrons so that the photoreceptor 11 is electrically charged. In the image forming apparatus of the present invention, other than the charging device 90, known members can be used. The electron emitting element 1 in the charging device 90 is preferably provided so as to be, for example, 3 mm to 5 mm apart from the photoreceptor 11. Further, it is preferable that a voltage of approximately 25 V is applied to the electron emitting element 1. An electron acceleration layer of the electron emitting element 1 should be configured such that 1 μA/cm² of electrons are emitted per unit of time in response to application of a voltage of 25V, for example.

The electron emitting device 10 which is used as the charging device 90 does not cause electric discharge. Therefore, the charging device 90 generates no ozone. Ozone is harmful to human bodies, and therefore regulated in various environmental standards. Even if ozone is not discharged to the outside of the apparatus, ozone deteriorates by oxidation an organic material such as the photoreceptor 1 or a belt inside the apparatus. However, such a problem can be solved by that the electron emitting device 10 of the present invention is used in the charging device 90 and further the image forming apparatus includes such a charging device 90.

Moreover, because the electron emitting element 1 has a high electron emission efficiency, the charging device 90 can efficiently carry out charging.

Further, the electron emitting device 10 serving as the charging device 90 is configured as a planar electron source. Therefore, the electron emitting device 10 is capable of charging the photoreceptor 11 on an area that has a width in a rotation direction. This provides many chances for charging a section of the photoreceptor 11. Therefore, the charging device 90 can perform a more uniform electric charging as compared to a wire charging device electrically charging line by line a section on the photoreceptor 11. Further, the charging device 90 has an advantage such that the applied voltage is approximately 10 V which is far lower than that of a corona discharge device which requires an applied voltage of a few kV.

### Embodiment 3

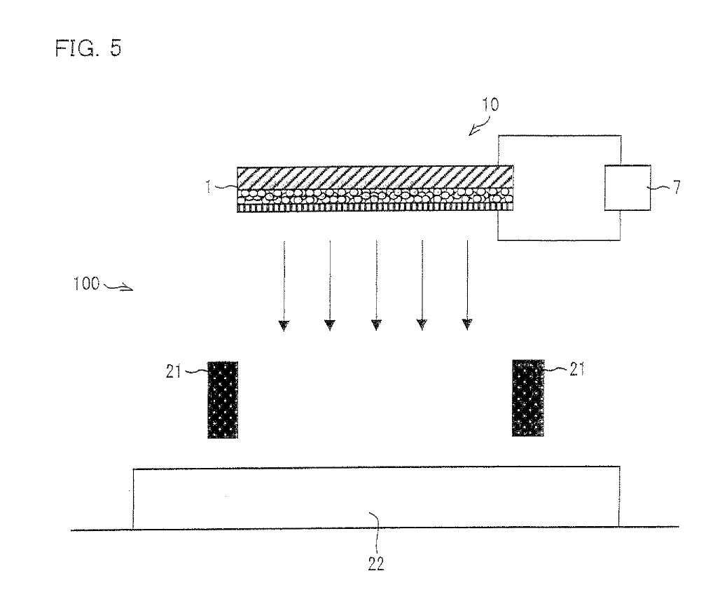

FIG. 5 shows an example of an electron-beam curing device 100 of the present invention including an electron emitting device 10 employing an electron emitting element of the present invention which is described in Embodiment 1.

The electron-beam curing device 100 includes the electron emitting device 10 including the electron emitting element 1 and a power supply 7 for applying a voltage to the electron emitting element 1, and an accelerating electrode 21 for accelerating electrons. In the electron-beam curing device 100, the electron emitting element 1 serving as an electron source emits electrons, and the electrons emitted are accelerated by the accelerating electrode 21 so that the electrons collide with a resist (an object to be cured) 22. Energy necessary for curing the general resist 22 is not more than 10 eV. In terms of energy, the accelerating electrode is not necessary. However, a penetration depth of an electron beam is determined by a function of energy of electrons. For example, in order to entirely cure the resist 22 having a thickness of 1 μm, an accelerating voltage of approximately 5 kV is required.

In a conventional general electron-beam curing device, an electron source is sealed in vacuum and caused to emit electrons by application of a high voltage (in a range of 50 kV to 100 kV). The electrons are taken out through an electron window and used for irradiation. According to the above electron emission method, when the electrons pass through the electron window, loss of a large amount of energy occurs in the electrons. Further, the electrons that reach the resist pass through the resist in the thickness direction because the electrons have high energy. This decreases energy utilization efficiency. In addition, because an area on which electrons are thrown at a time is small and irradiation is performed in a manner drawing with dots, throughput is low.

On the other hand, the electron-beam curing device of the present invention including the electron emitting device 10 can be expected to work in the atmosphere, and the electron-beam curing device does not need to be sealed in vacuum.

Further, the electron-beam curing device 100 can efficiently carry out irradiation of an electron beam because the electron emitting element 1 has a high electron emission efficiency.

The electron-beam curing device 100 is free from energy loss because the electrons do not pass through the electron window. This allows reducing an applied voltage. Moreover, since the electron-beam curing device 100 has a planar electron source, the throughput increases significantly. In a case where electrons are emitted in accordance with a pattern, it is possible to perform a maskless exposure.

### Embodiment 4

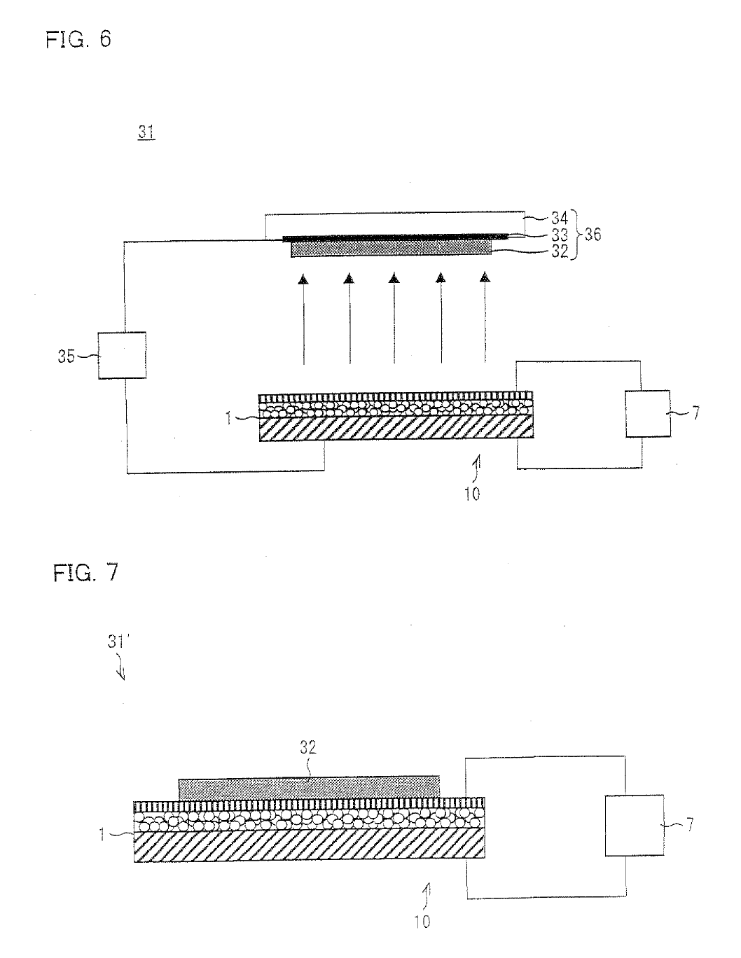

FIG. 6 through FIG. 8 show examples of respective light emitting devices 31, 31′ and 31″ of the present invention each including an electron emitting device 10 including an electron emitting element 1 which is described in Embodiment 1.

The light emitting device 31 illustrated in FIG. 6 includes the electron emitting device 10 including an electron emitting element 1 and a power supply 7 for applying a voltage to the electron emitting element 1, and a light-emitting section 36 having a laminated structure including a glass substrate 34 as a base material, an ITO film 33, and a luminous body 32. The light emitting section 36 is provided in a position that is apart from the electron emitting element 1 so that the luminous body 32 faces the electron emitting element 1.

Suitable materials of the luminous body 32 are materials that are excited by electrons and that correspond to red light emission, green light emission, and blue light emission, respectively. Examples usable as such materials corresponding to red are Y₂O₃:Eu, and (Y, Gd) Bo₃:Eu; examples usable as such materials corresponding to green are Zn₂SiO₄:Mn and BaAl₁₂O₁₉:Mn; and an example usable as such materials corresponding to blue is BaMgAl₁₀O₁₇:Eu²⁺. A film of the luminous body 32 is formed on the ITO film 33 which is formed on the glass substrate 34. It is preferable that the luminous body 32 is approximately 1 μm in thickness. Further, the ITO film 33 may have any thickness as long as the ITO film 33 can reliably have electric conductivity at the thickness. In the present embodiment, the ITO film 33 is set to 150 nm in thickness.

For forming a film of the luminous body 32, a mixture of epoxy resin serving as a binder and luminous-body particles is prepared, and a film of the mixture may be formed by a known method such as a bar coater method or a dropping method.

In this embodiment, in order to increase a brightness of light emitted from the luminous body 32, it is necessary to accelerate, toward the luminous body, electrons which are emitted from the electron emitting element 1. Accordingly, between the electrode substrate 2 of the electron emitting element 1 and the ITO film 33 of the light-emitting section 36, a power supply 35 should be provided in order to form an electric field for accelerating the electrons. In this case, it is preferable that: (i) a distance between the luminous body 32 and the electron emitting element 1 is 0.3 mm to 1 mm; a voltage applied by the power supply 7 is 18V; and a voltage applied by the power supply 35 is 500 V to 2000 V.

A light emitting device 31′ shown in FIG. 7 includes the electron emitting device 10 including an electron emitting element 1 and a power supply 7 for applying a voltage to the electron emitting element 1, and a luminous body 32. In the light emitting device 31′, the luminous body 32 is a planar luminous body which is provided on a surface of the electron emitting element 1. In the present embodiment, a layer of the luminous body 32 is formed on a surface of the electron emitting element 1, in such a manner that a mixture of epoxy resin serving as a binder and luminous body particles is prepared as described above and a film of the mixture is formed on the surface of the electron emitting element 1. Note that, because the electron emitting element 1 itself has a structure which is vulnerable to external force, the element may be damaged as a result of use of the bar coater method. Therefore, it is preferable to use the dropping method or the spin coating method.

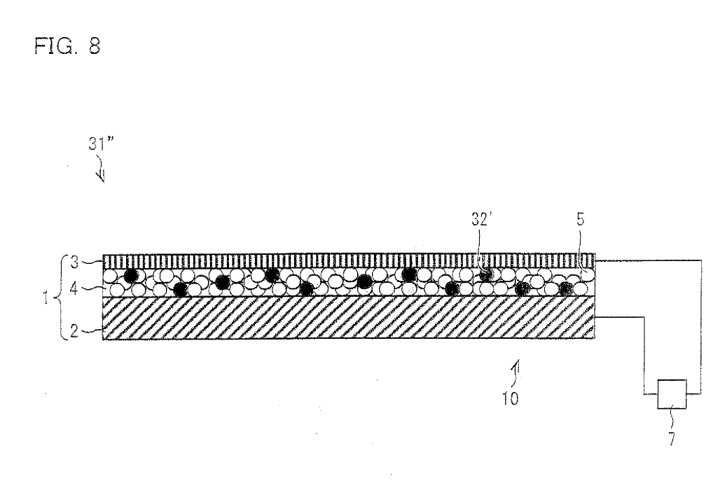

The light emitting device 31″ shown in FIG. 8 includes the electron emitting device 10 including an electron emitting element 1 and a power supply 7 for applying a voltage to the electron emitting element 1. Further, in a fine particle layer 4 of the electron emitting element 1, luminous fine particles as a luminous body 32′ are mixed in. In this case, the luminous body 32′ may be configured to also serve as the insulating fine particles 5. Generally, however, the luminous-body fine particles have a low electric resistance. As compared to electric resistance of the insulating fine particles 5, the electric resistance of the luminous-body fine particles is clearly lower. Therefore, when the luminous-body fine particles are mixed in replacement of the insulating fine particles 5, an amount of the luminous-body fine particles should be suppressed to a small amount. For example, when spherical silica particles (average particle diameter of 110 nm) are used as the insulating fine particles 5 and ZnS:Mg (average particle diameter of 500 nm) is used as the luminous-body fine particles, an appropriate mixture ratio by weight of the insulating fine particles 5 and the luminous-body fine particles is approximately 3:1.

In the above light emitting devices 31, 31′, and 31″, electrons emitted from the electron emitting element 1 are caused to collide with the corresponding luminous bodies 32 and 32′ so that light is emitted.

The light emitting devices 31, 31′, and 31″ can efficiently emit light because the electron emitting element has a high electron emission efficiency. Note that, though the light emitting devices 31, 31′ and 31″ of the present invention each employing the electron emitting device 10 are expected to work in the atmosphere, the light emitting devices 31, 31′ and 31″ sealed in vacuum can emit electrons more efficiently because electron emission current of such light emitting devices 31, 31′ and 31″ increases.

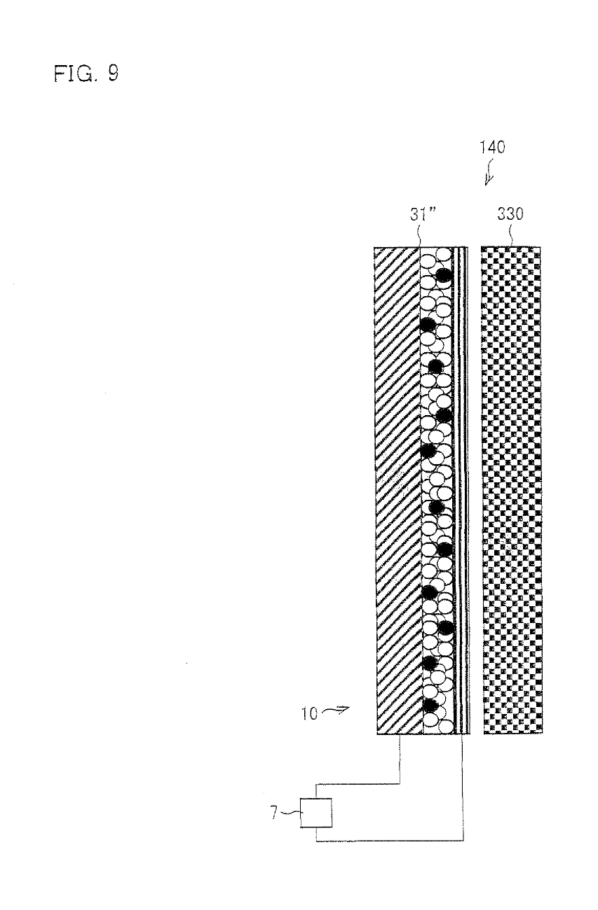

FIG. 9 illustrates an example of an image display device of the present invention which includes a light emitting device of the present invention. An image display device 140 illustrated in FIG. 9 includes a light emitting device 31″ illustrated in FIG. 8, and a liquid crystal panel 330. In the image display device 140, the light emitting device 31″ is provided behind the crystal panel 330 and used as a backlight. In cases where the light emitting device 31″ is used in the image display device 140, it is preferable that a voltage of 20 V to 35 V is applied to the light emitting device 31″. The light emitting device 31″ should be configured to emit, for example, 10 μA/cm² of electrons per unit of time at the voltage of 20 V to 35 V. Further, it is preferable that a distance between the light emitting device 31″ and the liquid crystal panel 330 is approximately 0.1 mm.

In cases where light emitting devices 31 illustrated in FIG. 6 are used as an image display device of the present invention, the light emitting devices 31 may be arranged in a matrix so as to form a shape that allows the light emitting devices 31 themselves serving as an FED to form and display an image. In such cases, it is preferable that a voltage applied to the light emitting device 31 is in a range of 20 V to 35 V. The light emitting device 31 should be configured to emit, for example, 10 μA/cm² of electrons per unit of time, at the applied voltage in the range of 20 V to 35 V.

### Embodiment 5

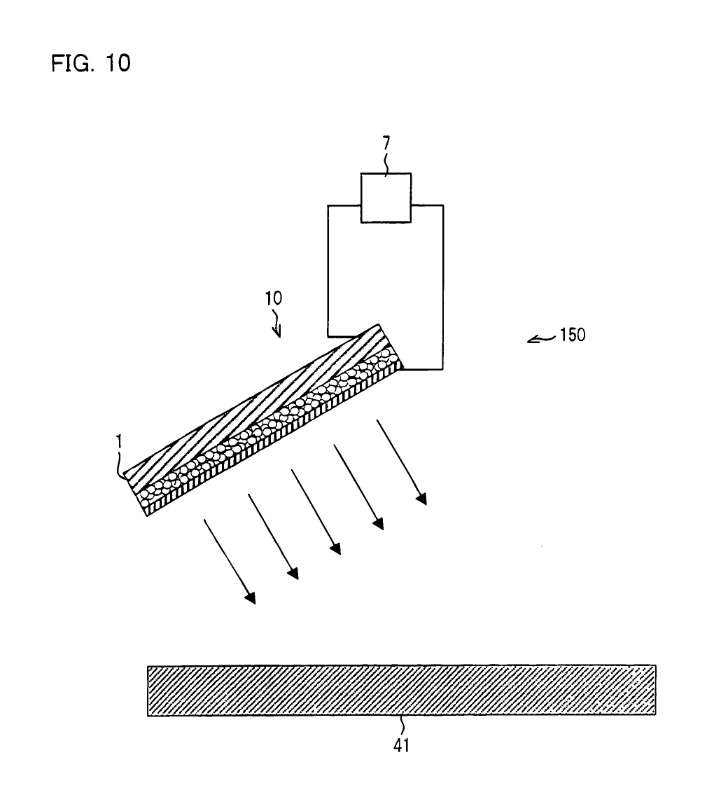

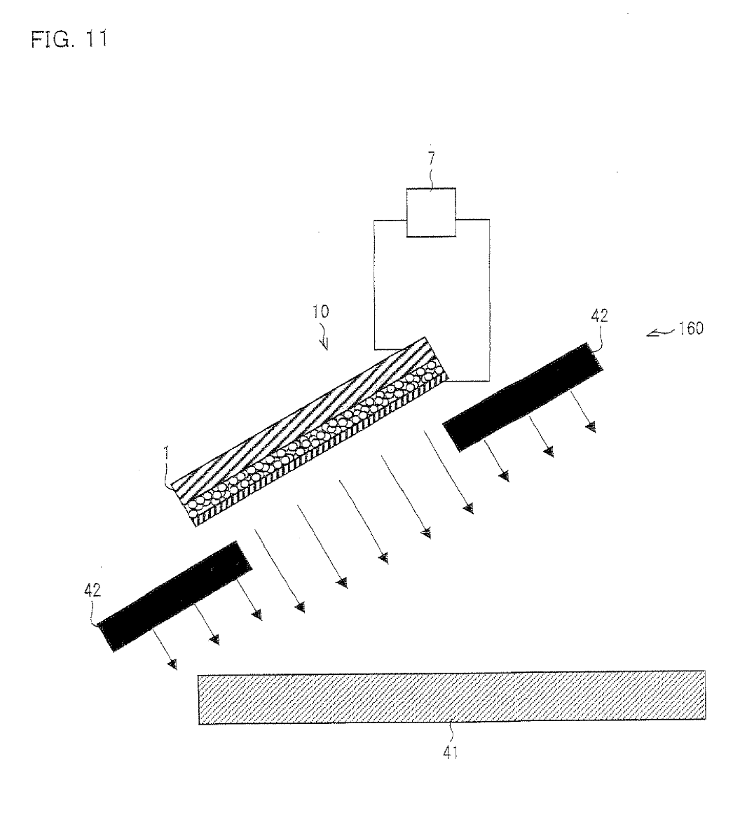

FIG. 10 and FIG. 11 show examples of air blowing devices 150 and 160 of the present invention each including an electron emitting device 10 employing an electron emitting element 1 of the present invention described in Embodiment 1. The following explanation deals with a case where each of the air blowing devices of the present invention is used as a cooling device. However, application of the air blowing device is not limited to a cooling device.

The air blowing device 150 illustrated in FIG. 10 includes the electron emitting device 10 including the electron emitting element 1 and a power supply 7 for applying a voltage to the electron emitting element 1. In the air blowing device 150, the electron emitting element 1 emits electrons toward an object 41 to be cooled so that ion wind is generated and the object 41 electrically grounded is cooled. In cases where the object 41 is cooled, it is preferable that a voltage of approximately 18 V is applied to the electron emitting element 1 and, at this applied voltage of approximately 18 V, the electron emitting element 1 emits, for example, 1 μA/cm² of electrons per unit of time in the atmosphere.

In addition to the arrangement of the air blowing device 150 illustrated in FIG. 10, an air blowing device 160 illustrated in FIG. 16 further includes a blowing fan 42. In the air blowing device 160 illustrated in FIG. 11, an electron emitting element 1 emits electrons toward an object 41 to be cooled and the blowing fan 42 blows the electrons toward the object 41 so that the object 41 electrically grounded is cooled down by generation of ion wind. In this case, it is preferable that an air volume generated by the blowing fan 42 is in a range of 0.9 L to 2 L per minute per square centimeter.

Now, a case where the object 41 is to be cooled by blowing air is considered. In a case where the object 41 is cooled by blowing only the atmospheric air with use of a fan or the like as in a conventional air blowing device or a conventional cooling device, cooling efficiency is low because a flow rate on a surface of the object 41 becomes 0 and the air in a section from which heat should be dissipated the most is not replaced. However, in cases where electrically charged particles such as electrons or ions are included in the air sent to the object 41, the air sent to the object 41 is attracted to the surface of the object 41 by electric force in the vicinity of the object 41. This makes it possible to replace the air in the vicinity of the surface of the object 41. In the present embodiment, because the air blowing devices 150 and 160 of the present invention blow air including electrically charged particles such as electrons or ions, the cooling efficiency is significantly improved.

Further, the air blowing devices 150 and 160 can more efficiently carry out the cooling due to a high electron emission efficiency of the electron emitting element 1. The air blowing devices 150 and 160 can be expected to work in the atmosphere.

### CONFIGURATIONS OF PRESENT INVENTION

As described above, an electron emitting element of the present invention includes: an electrode substrate; a thin-film electrode; and an electron acceleration layer that includes insulating fine particles but does not include conductive fine particles, the electron acceleration layer being provided between the electrode substrate and the thin-film electrode, the electron emitting element (i) accelerating electrons between the electrode substrate and the thin-film electrode at a time when a voltage is applied between the electrode substrate and the thin-film electrode and (ii) emitting the electrons from the thin-film electrode.

In the electron emitting element of the present invention, the insulating fine particles may contain an organic polymer or at least one of SiO₂, Al₂O₃, and TiO₂. When the insulating fine particles contain an organic polymer or at least one of SiO₂, Al₂O₃, and TiO₂, it becomes possible due to high insulating properties of the above substances to control a resistance value so that the resistance value is in a desired range.

In the electron emitting element of the present invention, the electron acceleration layer preferably has a layer thickness that is 1000 nm or less and equal to or greater than an average particle diameter of the insulating fine particles.

The smaller the layer thickness of the electron acceleration layer becomes, the more easily the current flows. However, the layer thickness is the smallest when the insulating fine particles of the electron acceleration layer are evenly placed as one layer on the electrode substrate so that the insulating fine particles do not overlap with each other (each insulating fine particle is not provided on top of another). Therefore, the minimum layer thickness of the electron acceleration layer is an average particle diameter of the insulating fine particles forming the electron acceleration layer. A case where the layer thickness of the electron acceleration layer is smaller than the average particle diameter of the insulating fine particles means a state in which the electron acceleration layer includes a section where the insulating fine particles is not present. In such a case, the electron acceleration layer does not function as an electron acceleration layer. Therefore, the average particle diameter is preferable as the lowest limit value of the layer thickness of the electron acceleration layer. The lowest limit value of the layer thickness of the electron acceleration layer is considered to be more preferably a layer thickness in a case where two or more insulating fine particles are accumulated. This is because, in a case where the electron acceleration layer has the layer thickness equal to a diameter of one constituent particle, leak current increases though an amount of current flowing in the electron acceleration layer increases. This weakens the intensity of the electric field exerted on the electron acceleration layer. As a result, electrons cannot be emitted efficiently. Meanwhile, in a case where the layer thickness is more than 1000 nm, a resistance of the electron acceleration layer increases and a sufficient current does not flow. As a result, a sufficient amount of electrons cannot be emitted.

In the electron emitting element of the present invention, the insulating fine particles preferably have an average particle diameter in a range of 7 nm to 400 nm. As described above, the layer thickness of the electron acceleration layer is preferably 1000 nm or less. However, when the average particle diameter of the insulating fine particles becomes greater than 400 nm, it becomes difficult to control the layer thickness of the electron acceleration layer so that the layer thickness becomes appropriate. Accordingly, it is preferable that the average particle diameter of the insulating fine particles is in the above range. In this case, distribution of particle diameters may be broad with respect to the average particle diameter. For example, respective particle diameters of the fine particles having an average particle diameter of 50 nm may be distributed in a range of 20 nm to 100 nm.

In the electron emitting element of the present invention, the insulating fine particles may be surface-treated. The insulating fine particles here may be surface-treated with silanol or a silyl group.

In production of the electron acceleration layer, when the insulting fine particles is applied to the electrode substrate after the insulating fine particles are dispersed in an organic solvent, dispersibility of the organic solvent improves if particle surfaces are treated with silanol or a silyl group. As a result, it becomes easy to obtain the electron acceleration layer in which the insulating fine particles are evenly dispersed. Further, because the insulating fine particles are evenly dispersed, it becomes possible to form an electron acceleration layer that has a small layer thickness and a high surface smoothness. As a result, the thin-film electrode on the electron acceleration layer can be formed thinly. As described above, the thinner the film thickness of the thin-film electrode which can ensure electric conductivity is, the more efficiently the electrons can be emitted.

In the electron emitting element of the present invention, the thin-film electrode may contain at least one of gold, silver, carbon, tungsten, titanium, aluminum, and palladium. Because the thin-film electrode contains at least one of gold, silver, carbon, tungsten, titanium, aluminum, and palladium, tunneling of electrons generated by the electron acceleration layer becomes more efficient because of a low work function of the above substances. As a result, it becomes possible to emit more electrons having high energy to the outside of the electron emitting element.

An electron emitting device of the present invention includes: any one of the electron emitting elements described above; and a power supply section for applying a voltage between the electrode substrate and the thin-film electrode.

According to the arrangement, electric conductivity is ensured so that sufficient current flows in the element and ballistic electrons can be highly efficiently and steadily emitted from the thin-film electrode.

Here, the power supply section may apply a DC voltage between the electrode substrate and the thin-film electrode.

By using the electron emitting device of the present invention in a light emitting device and an image display device including the light emitting device, it becomes possible to provide a light emitting device (i) that does not need to be sealed in vacuum, (ii) that steadily perform planar light emission, and (iii) that has a long life.

By using the electron emitting device of the present invention in an air blowing device or a cooling device, cooling at a high efficiency becomes possible as a result of utilization of a slip effect on a surface of an object to be cooled. Further, in the cooling, no electric discharge occurs and no harmful substances such as ozone and NOₓ are produced.

By using the electron emitting device of the present invention in a charging device and an image forming apparatus including the charging device, an object to be charged can be charged while no electric discharge occurs and no harmful substances such as ozone and NOₓ are produced.

By using an electron emitting device of the present invention in an electron-beam curing device, it becomes possible to perform electron-beam curing area by area. This makes it possible to allow a maskless process, thereby achieving low cost and high throughput.

In order to solve the problems mentioned above, a method of the present invention for producing an electron emitting element that includes: an electrode substrate; and a thin-film electrode, the electron emitting element (i) accelerating electrons between the electrode substrate and the thin-film electrode at a time when a voltage is applied between the electrode substrate and the thin-film electrode and (ii) emitting the electrons from the thin-film electrode, the method includes the steps of: forming, on the electrode substrate, an electron acceleration layer that includes insulating fine particles but does not include conductive fine particles; and forming the thin-film electrode on the electron acceleration layer.

According to the above method, it becomes possible to easily produce an electron emitting element that makes dielectric breakdown hard to occur and that is capable of emitting a steady and sufficient amount of electrons not only in vacuum but also under the atmospheric pressure.

In the method of the present invention for producing the electron emitting element, the step of forming the electron acceleration layer may include the sub-steps of: obtaining a dispersion solution in which the insulating fine particles are dispersed in a solvent; applying the dispersion solution on the electrode substrate; and drying the dispersion solution applied.

Further, the method of the present invention for producing the electron emitting element may include the step of baking the electron emitting element after the step of forming the acceleration layer or after the step of forming the thin-film electrode.

According to the method, after the step of forming the acceleration layer or after the step of forming the thin-film electrode, the electron emitting element is baked. As a result, a crack is formed in the electron acceleration layer. This makes it possible to provide the electron emitting element that emits a large amount of electrons.

In the above step of baking, the electron emitting element is baked preferably under a condition that does not cause the insulating fine particles to melt.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention can be suitably applied, for example, (i) to a charging device of image forming apparatuses such as an electrophotographic copying machine, a printer, and a facsimile; (ii) an electron-beam curing device; (iii) in combination with a luminous body, to an image display device; or (iv) by utilizing ion wind generated by electrons emitted from the electron emitting element, to a cooling device.

### REFERENCE SIGNS LIST

1 Electron emitting element
2 Electrode substrate
3 Thin-Film Electrode
4 Electron acceleration layer
5 Insulating fine particles
7 Power supply (Power supply section)
8 Counter Electrode
9 Insulating spacer
10 Electron emitting device
11 Photoreceptor
21 Acceleration Electrode
22 Resist (Object to be cured)
31, 31′, 31″ Light emitting device
32, 32′ Luminous body (Light emitting body)
33 ITO film
34 Glass substrate
35 Power Supply
36 Light emitting section
41 Object to be cooled
42 Air blowing fan
90 Charging device
100 Electron-beam curing device
140 Image display device
150 Air blowing device
160 Air blowing device
330 Liquid crystal panel

1. An electron emitting element comprising:
an electrode substrate;
a thin-film electrode; and
an electron acceleration layer that includes insulating fine particles but does not include conductive fine particles, the electron acceleration layer being provided between the electrode substrate and the thin-film electrode,
the electron emitting element (i) accelerating electrons between the electrode substrate and the thin-film electrode at a time when a voltage is applied between the electrode substrate and the thin-film electrode and (ii) emitting the electrons from the thin-film electrode.

2. The electron emitting element according to claim 1, wherein:
the insulating fine particles contain an organic polymer or at least one of SiO₂, Al₂O₃, and TiO₂.

3. The electron emitting element according to claim 1, wherein:
the electron acceleration layer has a layer thickness that is 1000 nm or less and equal to or greater than an average particle diameter of the insulating fine particles.

4. The electron emitting element according to claim 1, wherein:
the insulating fine particles have an average particle diameter in a range of 7 nm to 400 nm.

5. The electron emitting element according to claim 1, wherein:
the insulating fine particles are surface-treated.

6. The electron emitting element according to claim 5, wherein:
the insulating fine particles are surface-treated with silanol or a silyl group.

7. The electron emitting element according to claim 1, wherein:
the thin-film electrode contains at least one of gold, silver, carbon, tungsten, titanium, aluminum, and palladium.

8. An electron emitting device comprising:
an electron emitting element of claim 1; and
a power supply section for applying the voltage between the electrode substrate and the thin-film electrode.

9. The electron emitting element according to claim 8, wherein:
the power supply section applies a direct current voltage between the electrode substrate and the thin-film electrode.

10. A light emitting device comprising:
an electron emitting device according to claim 8; and
a luminous body,
the light emitting device causing the luminous body to emit light by causing the electron emitting device to emit electrons.

11. An image display device comprising:
a light emitting device according to claim 10.

12. An air blowing device comprising:
an electron emitting device according to claim 8,
the air blowing device causing the electron emitting device to emit electrons and blowing the electrons.

13. A cooling device comprising:
an electron emitting device according to claim 8,
the cooling device cooling an object to be cooled by causing the electron emitting device to emit electrons.

14. A charging device comprising:
an electron emitting device according to claim 8,
the charging device charging a photoreceptor by causing the electron emitting device to emit electrons.

15. An image forming apparatus comprising a charging device according to claim 14.

16. An electron-beam curing device comprising:
an electron emitting device according to claim 8,
the electron-beam curing device curing an object to be cured by causing the electron emitting device to emit electrons.

17. A method for producing an electron emitting element that includes:
an electrode substrate; and
a thin-film electrode,
the electron emitting element (i) accelerating electrons between the electrode substrate and the thin-film electrode at a time when a voltage is applied between the electrode substrate and the thin-film electrode and (ii) emitting the electrons from the thin-film electrode,
the method comprising the steps of:
forming, on the electrode substrate, an electron acceleration layer that includes insulating fine particles but does not include conductive fine particles; and
forming the thin-film electrode on the electron acceleration layer.

18. The method according to claim 17 for producing the electron emitting element, wherein:
the step of forming the electron acceleration layer includes the sub-steps of:
obtaining a dispersion solution in which the insulating fine particles are dispersed in a solvent;
applying the dispersion solution on the electrode substrate; and
drying the dispersion solution applied.

19. The method according to claim 17 for producing the electron emitting element, the method further comprising the step of:
baking the electron emitting element after the step of forming the electron acceleration layer or after the step of forming the thin-film electrode.

20. The method according to claim 19 for producing the electron emitting element, wherein:
in the step of baking the electron emitting element, the electron emitting element is baked under a condition that does not cause the insulating fine particles to melt.
